(19) United States
(12) Patent Application Publication
(10) Pub. No.: US 2010/0051105 A1
(43) Pub. Date: Mar. 4, 2010

(54) FLEXIBLE SUBSTRATE FOR II-VI COMPOUND SOLAR CELLS

(76) Inventor: Mustafa Pinarbasi, Morgan Hill, CA (US)

Correspondence Address: PILLSBURY WINTHROP SHAW PITTMAN LLP, P.O. BOX 10500, MCLEAN, VA, 22102, US

(21) Appl. No.: 12/198,782

(22) Filed: Aug. 26, 2008

(51) Int. Cl. H01L 31/04; H01L 31/18

(52) U.S. Cl. 136/262; 438/95; 257/E31.027

(57) ABSTRACT

A thin film solar including a II-VI compound semiconductor absorber layer and a stainless steel substrate is provided. The stainless steel flexible foil substrate includes about 10-25% chromium and about 0.50-2.25% molybdenum, and no nickel. Process yield of the solar cells manufactured on such stainless steel substrates is higher than 10% because of a very low defect density such as micro-cracks, pinholes, and adhesion failures between the substrate and the absorber layer.

### BACKGROUND

1. Field of the Invention

This invention relates to thin film solar cell fabrication methods and structures.

2. Description of the Related Art

Solar cells are photovoltaic (PV) devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce the cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA chalcopyrite compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0>y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications.

The structure of a conventional Group IBIIIAVIA compound photovoltaic cell such as a Cu(In,Ga,Al)(S,Se,Te)₂ thin film solar cell is shown in FIG. 1. The device 10 is fabricated on a substrate 11, such as a sheet of glass, a sheet of metal, an insulating foil or web, or a conductive foil or web. The absorber film 12, which includes a material in the family of Cu(In,Ga,Al)(S,Se,Te)₂, is grown over a conductive layer 13, which is previously deposited on the substrate 11 and which acts as the electrical contact to the device. Various conductive layers comprising Mo, Ta, W, Ti, and stainless steel etc. have been used in the solar cell structure of FIG. 1. If the substrate itself is a properly selected conductive material, it is possible not to use a conductive layer 13, since the substrate 11 may then be used as the ohmic contact to the device. After the absorber film 12 is grown, a transparent layer 14 such as a CdS, ZnO or CdS/ZnO stack is formed on the absorber film. Radiation 15 enters the device through the transparent layer 14. Metallic grids (not shown) or a grid pattern may also be deposited over the transparent layer 14 to reduce the effective series resistance of the device. A variety of materials, deposited by a variety of methods, can be used to provide the various layers of the device shown in FIG. 1. It should be noted that although the chemical formula for a CIGS(S) layer is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

One approach to reduce the cost of thin film photovoltaics is to process thin film CIGS(S) type solar cells on flexible metallic foils so that the depositions of multiple films or layers constituting the solar cell structure, such as the contact layer, the CIGS(S) absorber film, the transparent layer and the metallic grids, may all be performed over the flexible foil substrate in a roll-to-roll fashion. This way a long (such as 3000-10000 ft long) foil substrate may be processed in relatively compact process tools to form a roll of solar cells, which may then be cut and used in module fabrication. Choice of the substrate material is very important for thin film solar cells since the layers in these device structures are only 1-5 micrometers thick and they get affected by the nature of the substrate during and after processing. For example, the typical thicknesses of the contact layers, the CIGS absorber layers and transparent layers are, 0.3-1 micrometer, 1-3 micrometer and 0.1-0.5 micrometers, respectively. The most popular metallic substrates for CIGS solar cells are “430 stainless steel” foils and aluminum alloy foils. These are satisfactory substrates for demonstration of devices. However, the much needed manufacturing process yield improvements require identification and development of metallic foil substrates that are better suited for large volume roll-to-roll processing and manufacturing of CIGS solar cell and modules.

### SUMMARY

The embodiments of the present invention relate to thin film CIGS solar cell structures. In one aspect there is provided a specific flexible metallic foil substrate that improves device performance and manufacturing process yield.

In another aspect, there is provided a thin film solar cell structure, comprising: a stainless steel flexible foil substrate comprising about 10-25% chromium and about 0.50-2.25% molybdenum, wherein the stainless steel flexible foil substrate excludes nickel; a II-VI compound semiconductor layer formed over the stainless steel flexible foil substrate; and a transparent layer formed on the II-VI compound semiconductor layer.

In another aspect, there is provided a method of fabricating a thin film solar cell comprising: providing a stainless steel flexible foil substrate comprising about 10-25% chromium and about 0.50-2.25% molybdenum, wherein the stainless steel flexible foil substrate excludes nickel; depositing a contact layer over a surface of the stainless steel flexible foil substrate; forming a Group IBIIIAVIA compound layer on the contact layer; and forming a transparent layer on the Group IBIIIAVIA compound layer.

This and other aspects and advantages, among others, are described further hereinbelow.

### BRIEF DESCRIPTION OF THE DRAWINGS

FIG. 1 is a schematic view of a prior art solar cell structure; and

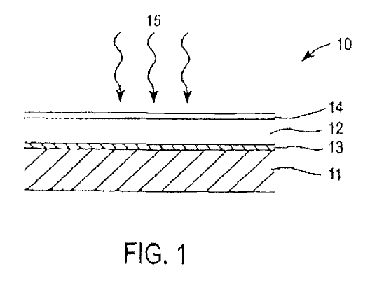

FIG. 2 is a solar cell structure using a stainless steel foil substrate of the present invention.

### DETAILED DESCRIPTION

The present invention provides a flexible foil substrate that enhances the efficiency and manufacturing yield of flexible Group IBIIIAVIA thin film solar cells such as CIGS(S) type solar cells. Although the invention will be described using a CIGS solar cell as an example, it will be appreciated that the invention is applicable to any flexible thin film solar cell employing a Group IBIIIAVIA compound semiconductor absorber film. In an embodiment of the present invention, a flexible foil substrate may be made of a stainless steel comprising about 10-25% chromium (Cr) and about 0.50-2.5% molybdenum (Mo), and no nickel (Ni). An exemplary stainless steel that is within this composition range may be the AISI type 436 stainless steel which comprises 16-18% Cr and 0.75-1.25% Mo. The 436 steel does not contain any nickel.

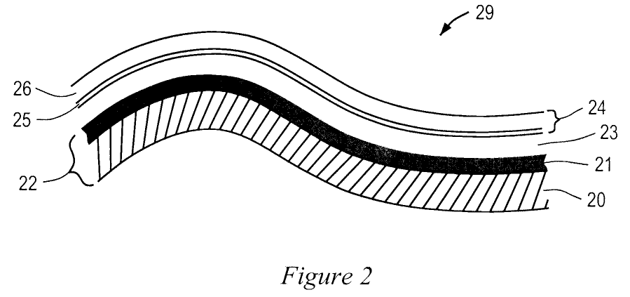

FIG. 2 shows the structure of a flexible CIGS solar cell 29 formed in accordance with the present invention. The solar cell 29 comprises a base 22 which comprises a flexible foil substrate 20 and a contact layer 21. As mentioned above, an exemplary material for the flexible foil substrate may be the AISI type 436 stainless steel. The thickness of the flexible substrate 20 may be in the range of 25-125 micrometers, preferably 35-50 micrometers. A CIGS absorber layer 23 is formed over the contact layer 21. The cell is completed by deposition of a buffer layer 25 and a transparent conductive layer 26 over the CIGS absorber layer 23. The buffer layer 25 and the transparent conductive layer 26 form a transparent layer 24 through which light enters the device. The contact layer 21 may be a multi-layer structure itself comprising materials that provide; i) good diffusion barrier action against iron (Fe) diffusion into the CIGS absorber layer 23, ii) good ohmic contact to the CIGS absorber layer 23, and, iii) good adhesion to the flexible “436 stainless steel” substrate 20. Such materials include, but are not limited to tungsten (W), tantalum (Ta), molybdenum (Mo), titanium (Ti), chromium (Cr), ruthenium (Ru) and iridium (Ir), their alloys and/or nitrides.

The CIGS absorber layer 23 may be deposited on the contact layer 21 using various techniques well known in the field. These techniques include evaporation, sputtering, ink deposition, electroplating, two-stage techniques, etc. The buffer layer 25 is often a sulfide compound such as cadmium sulfide and indium sulfide. The transparent conductive layer 26 may be a transparent conductive oxide (TCO) such as zinc oxide (ZnO), indium tin oxide (ITO), and indium zinc oxide (IZO). The transparent conductive layer 26 may also be a stacked layer of the TCOs listed above. There may be a grid pattern (not shown) formed over the transparent layer 24. The important aspect of the structure of the flexible CIGS solar cell 29 is its substrate. Use of a “436 stainless steel” foil as the substrate material offers several benefits over the prior art “430 stainless steel” substrate. The chemical composition of the “430 stainless steel” is; 0.12% C, 1% Mn, 1% Si, 0.04% P, 0.03% S, 16-18% Cr and the balance Fe, all percentages being in weight percent. The chemical composition of the “436 stainless steel” additionally comprises 0.75-1.25% Mo and 0.6% (Nb+Ta). It is observed that, as opposed to the prior art steels including Cr such as AISI type 430 steel, use of the stainless steels including Cr and Mo as the substrate for thin film solar cells improves process window and yield high efficiency devices. For example, a Mo layer was sputter deposited as the contact layer on a prior art foil made of AISI type 430 steel with 50 micrometer thickness in a roll-to-roll sputtering tool. The width of the foil substrate was 13.5″. A tension of about 150 lbs was applied across the foil while the Mo layer was sputtered from three targets placed around a cooling drum. The power to the cathodes was fixed with the goal of obtaining 300 nm thick Mo on one face of the web at a web speed of 3 ft/minute. However, the speed of the web could be varied to optimize the physical appearance of the coated surface. It was observed that for slow speeds, the web got extremely hot while passing in front of the cathodes and this resulted in deformation of the foil substrate and cracking of the deposited Mo layer. Solar cells fabricated in these regions of the web had low efficiencies and poor mechanical adhesion. For the “430 stainless steel” foil substrates, the speed of the web had to be increased to avoid this problem. However at the increased speed, only about 150 nm of Mo could be deposited on the face of the web. This thickness is outside the specifications which are established to assure that that 300 nm thick Mo layer would act as a diffusion barrier for Fe and therefore protect the CIGS absorber layer from diffusion of Fe from the substrate. When the “436 stainless steel” foil with the same thickness was used under the same processing conditions, however, the speed of the web could be reduced to 3 ft/minute to deposit the 300 nm thick Mo layer on the face of the web without any of the mechanical defects described above.

Furthermore, it was determined that defects such as micro-cracks, pinholes, and adhesion failures between the substrate and the CIGS layer were minimized for CIGS layers grown on “436 stainless steel” foils compared to those grown on “430 stainless steel” foils. Therefore, the process yield for high efficiency (higher than 9%) solar cells was better for the “436 stainless steel” substrate.

The reasons for the reduced defectivity and improved solar cell yield for CIGS layers processed on “436 stainless steel” foil substrates are not fully understood. However, it is known that some of the mechanical properties of the 430 and 436 stainless steel are different. For example, the tensile strength and the 0.2% yield strength of “436 stainless steel” in annealed sheet form are 530 Mpa and 365 Mpa, respectively (ASM Specialty Handbooks-Stainless Steels, p. 21, 1994). These values for the “430 stainless steel” are 450 Mpa and 205 Mpa. In roll-to-roll manufacturing of CIGS solar cells the foil substrate is first cleaned and then coated by the contact layer, the CIGS layer, the buffer layer and the transparent layer, all in a roll-to-roll fashion. After deposition of the transparent layer, a finger pattern is also deposited in a roll-to-roll tool. Unlike batch processing where individually cut substrates go through the above mentioned process steps, roll-to-roll processing exerts high forces on the portions of the foil substrate that is coated by various layers. It is not uncommon that roll-to-roll processing tools operate at tension levels varying in the range of 50-500 lbs for a 12″ wide web. In other words the web is kept under tension during the deposition of the various layers forming the solar cell structure. Some of these processing steps such as sputtering of the contact layer, growth of the CIGS layer and sputtering of the transparent layer involve heating of the foil substrate. During sputter deposition of the contact layer, for example, the foil substrate temperature may go up to the 150-300° C. range. During CIGS layer growth the temperature of the foil substrate typically goes to the 400-600° C. range. Therefore, considerations for selection of a foil substrate for roll-to-roll processing may be very different than the case where batch processing is used for CIGS solar cell fabrication.

The higher tensile strength and yield strength of the “436 stainless steel” foil substrate compared to the “430 stainless steel” foil substrate may be a benefit for roll-to-roll processing where the foil substrate is subjected to high temperatures at high tension. It should be appreciated that defectivity in finished solar cell would be lower if the foil substrate stays mechanically stable throughout the roll-to-roll processes during which various layers of the solar cell structure are formed over the foil substrate. The linear thermal expansion coefficients along the “c” crystallographic axis for CIS and CGS are about 7.9×10⁻⁶ K⁻¹ and 5.2×10⁻⁶ K⁻¹, respectively. The mean coefficients of thermal expansion of the “430 stainless steel” and the “436 stainless steel” are 10.4 micrometer/meter/° C. and 9.3 micrometer/meter/° C., respectively. As can be appreciated from these properties, the match between the “436 stainless steel” and CIGS is expected to be better than the match between the “430 stainless steel” and CIGS, from the thermal expansion coefficient point of view. This also may reduce defects in the final solar cell structure employing the “436 stainless steel” foil substrate.

Unlike the “430 stainless steel”, the “436 stainless steel” substrate comprises Mo, and Nb and/or Ta. These refractory materials are all compatible with CIGS absorber and their reactivity is limited with Group VIA materials such as Se, which is present during CIGS film growth. In fact the refractory materials such as Mo, Ta and Nb are used as contact layers in CIGS solar cell structures. Therefore, addition of these refractory materials to the composition of the substrate may only improve the chemical compatibility of the substrate with the processing steps employed during CIGS film formation. Materials such as Ni, on the other hand, react excessively with Group VIA materials such as Se and S. Refractory metals such as Mo and Ta may make physical and electrical contact with a CIGS layer grown over them without affecting its properties. Nickel, on the other hand is a poison in CIGS if it diffuses into the compound during its growth. Although the invention is described for use in Group IBIIIAVIA thin film compound solar cell manufacturing, it should be noted that it is also applicable for the construction of Group IIBVIA thin film compound solar cells such as cadmium telluride (CdTe) solar cells, where the Group IB and Group IIIA materials are replaced with a Group IIB material. In this case the absorber layer would be changed from a Group IBIIIAVIA compound layer to a to a Group IIBVIA compound layer in FIG. 2. It should be noted that both Group IIBVIA and Group IBIIIAVIA materials may generally be referred to as “II-VI Compound Semiconductors”. CdTe films for thin film solar cell applications may be grown by various well established deposition techniques such as evaporation, sputtering, electroplating, close-spaced vapor transport and close-spaced sublimation.

Although the present invention is described with respect to certain preferred embodiments, modifications thereto will be apparent to those skilled in the art.

I claim:

1. A thin film solar cell structure, comprising:
a stainless steel flexible foil substrate comprising about 10-25% chromium and about 0.50-2.25% molybdenum, wherein the stainless steel flexible foil substrate excludes nickel;
a II-VI compound semiconductor layer formed over the stainless steel flexible foil substrate; and
a transparent layer formed on the II-VI compound semiconductor layer.

2. The structure of claim 1, wherein the II-VI compound semiconductor layer comprises a Group IIBVIA material layer.

3. The structure of claim 2, wherein the Group IIBVIA material layer is a CdTe layer.

4. The structure of claim 3 wherein the thickness of the stainless steel flexible foil substrate is in the range of 25-125 micrometers, and wherein the structure further comprises a contact layer disposed between the stainless steel flexible foil substrate and the CdTe layer, the contact layer comprising one of tungsten, tantalum, molybdenum, titanium, chromium, ruthenium and iridium, their alloys and nitrides.

5. The structure of claim 4 wherein the transparent layer comprises a sulfide based buffer layer formed on the CdTe layer and a transparent conductive layer formed on the sulfide based buffer layer, and wherein the transparent conductive layer comprises at least one of zinc oxide, indium zinc oxide and indium tin oxide.

6. The structure of claim 1, wherein the II-VI compound semiconductor layer comprises a Group IBIIIAVIA material layer.

7. The structure of claim 6, wherein the Group IBIIIAVIA material layer comprises copper, gallium, indium and selenium.

8. The structure of claim 7, wherein the thickness of the stainless steel flexible foil substrate is in the range of 25-125 micrometers, and wherein the structure further comprises a contact layer disposed between the stainless steel flexible foil substrate and the Group IBIIIAVIA material layer, the contact layer comprising one of tungsten, tantalum, molybdenum, titanium, chromium, ruthenium and iridium, their alloys and nitrides.

9. The structure of claim 8, wherein the transparent layer comprises a sulfide based buffer layer formed on the Group IBIIIAVIA material layer and a transparent conductive layer formed on the sulfide based buffer layer, and wherein the transparent conductive layer comprises at least one of zinc oxide, indium zinc oxide and indium tin oxide.

10. The structure of claim 1 wherein the transparent layer comprises a sulfide based buffer layer formed on the II-VI compound semiconductor layer and a transparent conductive layer formed on the sulfide based buffer layer, and wherein the transparent conductive layer comprises at least one of zinc oxide, indium zinc oxide and indium tin oxide.

11. The structure of claim 10 further comprising a terminal layer formed over the transparent conductive layer.

12 The structure of claim 11 wherein the terminal layer includes a busbar and conductive fingers attached to the busbar.

13. The structure of claim 10 further comprising a contact layer disposed between the stainless steel flexible foil substrate and the II-VI compound semiconductor layer, wherein the contact layer comprises one of tungsten, tantalum, molybdenum, titanium, chromium, ruthenium and iridium, their alloys and nitrides.

14. The structure of claim 1, wherein the thickness of the stainless steel flexible foil substrate is in the range of 25-125 micrometers.

15. The structure of claim 1, wherein the stainless steel flexible foil substrate further comprises about 0.02-0.15% carbon, about 1% silicon, about 1% manganese, less than about 0.04% phosphorus, less than about 0.03 sulfur, about 0.06% niobium and tantalum and iron being the balance.

16. A method of fabricating a thin film solar cell comprising:
providing a stainless steel flexible foil substrate comprising about 10-25% chromium and about 0.50-2.25% molybdenum, wherein the stainless steel flexible foil substrate excludes nickel;
depositing a contact layer over a surface of the stainless steel flexible foil substrate;
forming a Group IBIIIAVIA compound layer on the contact layer; and
forming a transparent layer on the Group IBIIIAVIA compound layer.

17. The method of claim 16 further comprising depositing a contact layer on the surface of the stainless steel flexible foil substrate, the contact layer comprising one of tungsten, tantalum, molybdenum, titanium, chromium, ruthenium and iridium, their alloys and nitrides.

18. The method of claim 17, wherein the step of forming the Group IBIIIAVIA compound layer comprises forming a precursor comprising at least one Group IB material and at least one Group IIIA material on the contact layer, and reacting the precursor by applying heat at a temperature range of 350-600° C.

19. The method of claim 18, wherein forming the precursor comprises:
depositing a Group IB material layer and a Group IIIA material layer over the contact layer, wherein the Group IB material layer comprises one of copper and silver and the Group IIIA material layer comprises at least one of one of indium and gallium; and
depositing a Group VIA material layer over the Group IIIA material layer, wherein the Group VIA material layer comprises at least one of selenium and sulfur.

20. The method of claim 19, wherein the steps of depositing the Group IB, Group IIIA and Group VIA material layers comprise one of electrodeposition, sputtering, ink deposition and evaporation.

21. The method of claim 16, wherein the step of forming the transparent layer comprises forming a sulfide based buffer layer on the Group IBIIIAVIA compound layer, and forming a transparent conductive layer on the sulfide based buffer layer.

22. The method of claim 21, wherein the sulfide based buffer layer comprises one of cadmium sulfide and indium sulfide, and the transparent conductive layer comprises at least one of zinc oxide, indium zinc oxide and indium tin oxide.

23. The method of claim 16 further comprising forming a terminal layer formed on the transparent layer, wherein the terminal layer comprises busbars and conductive fingers.
